(19) United States
(12) Patent Application Publication
(10) Pub. No.: US 2012/0280362 A1
(43) Pub. Date: Nov. 8, 2012

(54) SIMPLE ROUTE FOR ALKALI METAL INCORPORATION IN SOLUTION-PROCESSED CRYSTALLINE SEMICONDUCTORS

(75) Inventors: Yang Yang, Los Angeles, CA (US); Wei-Jen Hou, Cerritos, CA (US); Sheng-Han Li, Los Angeles, CA (US); Chun-Chih Tung, Cerritos, CA (US)

(73) Assignee: The Regents of the University of California, Oakland, CA (US)

(21) Appl. No.: 13/516,997

(22) PCT Filed: Dec. 20, 2010
(86) PCT No.: PCT/US10/61323

§ 371 Date: Jun. 18, 2012

Related U.S. Application Data
(60) Provisional application No. 61/288,077, filed on Dec. 18, 2009.

(51) Int. Cl. H01B 1/10; H01L 29/12; H01L 21/20

(52) U.S. Cl. 257/613; 252/519.4; 438/478; 257/E29.068; 257/E21.09

(57) ABSTRACT

A precursor solution for producing a semiconductor includes at least one of an alkali metal or an alkali metal compound dissolved in a solvent, and a metal chalcogenide dissolved in the solvent. A method of producing a precursor solution for a semiconductor includes preparing a first precursor solution that has at least one of an alkali metal or an alkali metal compound dissolved in a first solvent, preparing a second precursor solution that has a metal chalcogenide dissolved in a second solvent, and combining the first and second precursor solutions to obtain the precursor solution for producing the semiconductor. A method of producing a semiconductor device includes providing a precursor solution for producing a semiconductor layer on a substructure, and forming a layer of the precursor solution on the substructure. The precursor solution includes at least one of an alkali metal or an alkali metal compound dissolved in a solvent, and a metal chalcogenide dissolved in the solvent.

### CROSS-REFERENCE OF RELATED APPLICATION

This application claims priority to U.S. Provisional Application No. 61/288,077 filed Dec. 18, 2009, the entire contents of which are hereby incorporated by reference.

This invention was made with U.S. Government support of Grant Nos. DMR0507294, awarded by the National Science Foundation. The U.S. Government has certain rights in this invention.

### BACKGROUND

1. Field of Invention

The claimed embodiments of the current invention relate to semiconductors, and more particularly to semiconductors and semiconductor devices produced from improved precursor solutions as well as to the improved precursor solutions.

2. Discussion of Related Art

Numerous efforts have been attempted to develop solution-processed routes for semiconductors as a more economical, large-scale production process. Various deposition methods such as electrodepositing, doctor blading, bar coating, and inkjet printing have been demonstrated on semiconductor materials for use in transistors, memory devices, light-emitting diodes, and solar cells. However, almost all methods demonstrated thus far suffer a major drawback, i.e., small grain size in the resulting material. This is import because large grain size of the semiconductor material is a critical factor in the performance of the resulting electronic devices.

This has led to some conventional methods which rely on forming the semiconductor material on sodium lime glass. However, this approach greatly limits the type of devices that can be produced and only provides small improvements. Other groups have deposited a layer of sodium on which the semiconductor is formed in such a way that the sodium diffuses into the semiconductor. This approach requires additional processing steps, including heating which can limit the types of devices that can be produced. Furthermore, this also only leads to small improvements since the amount of sodium that diffuses into the semiconductor layer drops off rapidly with distance from the sodium layer. Consequently, only thin semiconductor layers result in improved grain sizes with this method. Furthermore, such semiconductor layers cannot be produced in this way on complex underlying structures that may be sensitive to the high temperatures necessary for such a process.

For examples of conventional methods of sodium introduction into CIS thin films, see A. N. Tiwari, Prog. Photovolt: Res. Appl. 7, 393-397 (1999); M. Powalla, Thin Solid Films 387, 2001.33-36; and A. N. Tiwari, Thin Solid Films 480-481, (2005) 55-60, for example. However, as noted above, such methods of Na incorporation have been found to have many problems and are thus of quite limited utility. Therefore, there remains a need for improvements in solution processing of semiconductors and improved methods of producing semiconductor devices.

### SUMMARY

A precursor solution for producing a semiconductor according to an embodiment of the current invention includes at least one of an alkali metal or an alkali metal compound dissolved in a solvent, and a metal chalcogenide dissolved in the solvent.

A method of producing a precursor solution for producing a semiconductor according to an embodiment of the current invention includes preparing a first precursor solution that has at least one of an alkali metal or an alkali metal compound dissolved in a first solvent, preparing a second precursor solution that has a metal chalcogenide dissolved in a second solvent, and combining the first and second precursor solutions to obtain the precursor solution for producing the semiconductor.

A method of producing a semiconductor device according to an embodiment of the current invention includes providing a precursor solution for producing a semiconductor layer on a substructure, and forming a layer of the precursor solution on the substructure. The precursor solution includes at least one of an alkali metal or an alkali metal compound dissolved in a solvent, and a metal chalcogenide dissolved in the solvent.

Semiconductor devices according to some embodiments of the current invention are produced according to the methods according to some embodiments of the current invention.

### BRIEF DESCRIPTION OF THE DRAWINGS

Further objectives and advantages will become apparent from a consideration of the description, drawings, and examples.

FIGS. 1A and 1B show cross-sectional SEM micrographs of CuInSSe deposited on a molybdenum film after annealing at 500° C. in Ar. The CuInSSe film was cast from (a) pristine CuInSSe precursor solution (FIG. 1A) and (b) Na-incorporated CuInSSe precursor solution (FIG. 1B) according to an embodiment of the current invention.

FIG. 2 shows J-V characteristics of CuInSSe solar cells measured under AM 1.5G at 100 mW/cm² illustrating results according to an embodiment of the current invention.

FIG. 3 shows J-V characteristics of CuInSSe solar cells measured under dark conditions illustrating results according to an embodiment of the current invention.

FIG. 4 is a schematic illustration of a tandem photo-voltaic device in serial connection according to an embodiment of the current invention.

FIG. 5 is a schematic illustration of a tandem photo-voltaic device in parallel connection according to an embodiment of the current invention.

### DETAILED DESCRIPTION

Some embodiments of the current invention are discussed in detail below. In describing embodiments, specific terminology is employed for the sake of clarity. However, the invention is not intended to be limited to the specific terminology so selected. Standard symbols for various atomic elements are used throughout. A person skilled in the relevant art will recognize that other equivalent components can be employed and other methods developed without departing from the broad concepts of the current invention. All references cited anywhere in this specification are incorporated by reference as if each had been individually incorporated.

According to some embodiments of the current invention, we provide a simple route to increasing the grain size of crystalline semiconductors by use of alkali metals. Furthermore, it was also observed that such addition of alkali metals into the semiconductor material can have a significant effect in passivating the grain boundaries in the crystalline semiconductor.

Our group has previously developed solution-processing methods for producing semiconductor devices, such as described in international application number PCT/US2010/037469 filed Jun. 4, 2010, U.S. Provisional Application No. 61/184,104 filed Jun. 4, 2009. and U.S. Provisional Application No. 61/239,960 filed Sep. 4, 2009, the entire contents of which are hereby incorporated by reference. The precursor materials and methods of production of the current invention can be, but are not required to be, used in conjunction with such solution processing methods.

An embodiment of the current invention provides a precursor solution for producing a semiconductor that includes at least one of an alkali metal or an alkali metal compound dissolved in a solvent, and a metal chalcogenide dissolved in the solvent. The metal chalcogenides can include at least one of the elements Cu, In, Ga, Zn, Sn, Na, K, Al and P. In some embodiments the metal chalcogenides can include at least one of Cu₂Se, Cu₂Te, In₂S₃, In₂Te₃, CdTe, CdSe, CdS, Ga₂S₃, and Ga₂Se₃. In one example, the metal chalcogenides can include both In₂Se₃ and Cu₂S. However, the broad concepts of the current invention are not limited to only this particular example.

The solvent of the precursor solution can be, but is not limited to, hydrazine. The precursor solution can include at least one of lithium (Li), sodium (Na), potassium (K), rubidium (Rb), cesium (Cs) or francium (Fr) as an elemental alkali metal or in an alkali metal compound according to some embodiments of the current invention. For example, the alkali metal compound can be an alkali metal salt according to some embodiments of the current invention. For example, the alkali metal compound can be a carbonate, hydroxide or chalcogenide derivative alkali metal compound according to some embodiments of the current invention. In some embodiments, an alkali metal or alkali metal compound that includes sodium has been found to be useful.

Another embodiment of the current invention is directed to a method of producing a precursor solution for producing a semiconductor. The method includes preparing a first precursor solution that includes at least one of an alkali metal or an alkali metal compound dissolved in a first solvent, preparing a second precursor solution that includes a metal chalcogenide dissolved in a second solvent, and combining the first and second precursor solutions to obtain the precursor solution for producing the semiconductor. The general concepts of the current invention are not limited to only producing first and second precursor solutions to combine to provide the precursor solution for producing the semiconductor. For example, the method can further include preparing a third precursor solution that has a second metal chalcogenide dissolved in a third solvent prior to the combining, and combining the third precursor solution with at least one of the first and second precursor solutions prior to the combining or during the combining to provide the precursor solution for producing the semiconductor. This can be used to combine two or more metal chalcogenides and/or two or more alkali metals, for example. Furthermore, the solvents can be different or the same solvents, depending on the particular applications. Hydrazine was found to be a suitable solvent for some embodiments of the current invention. In addition, the various materials and combinations of materials specified above in regard to precursor materials according to various embodiments of the current invention can also be used in the methods of producing precursors according to some embodiments of the current invention.

Another embodiment of the current invention is directed to a method of producing a semiconductor device. The method includes providing a precursor solution for producing a semiconductor layer on a substructure, and forming a layer of the precursor solution on the substructure. The precursor solution includes at least one of an alkali metal or an alkali metal compound dissolved in a solvent, and a metal chalcogenide dissolved in the solvent. The various precursor materials described above can be used in various embodiments of making a semiconductor device according to some embodiments of the current invention.

The substructure can be a complex substructure that includes a plurality of layers of materials according to some embodiments of the current invention. For example, in some embodiments the substructure can include one or more sub-device such as to provide a tandem semiconductor device that has at least two tandem semiconductor sub-devices. The substructure can include one or more substrate according to some embodiments of the current invention. The substrates can be rigid or flexible substrates and can be of various materials, including, but not limited to glass, plastic metal foils, etc.

The method of producing a semiconductor device can further include additional processing prior to and/or subsequent to forming the layer of the precursor solution on the substructure. For example, the substructure can be brought to a predetermined temperature by either heating and/or cooling such that volatile components of the layer of the precursor solution of evaporate and/or migrate from the layer as the layer of precursor solution becomes the semiconductor layer. It can be desirable in some embodiments to control the temperature such that complex substructures are not damaged, for example.

Further embodiments of the current invention include semiconductor devices produced according to methods and/or with precursor materials according to some embodiments of the current invention.

### EXAMPLES

The following example illustrates an approach for Na incorporation through solution-processing according to an embodiment of the current invention. This approach can offer great control in the doping level and is compatible with the solution-processing of CISS thin film solar cell.

### Experimental Procedures

The sodium solution was prepared by placing 1 mmol of elemental sodium or Na₂Se in a screw cap glass vial. 0.5 mL of hydrazine (N₂H₄) solution was then added drop-wise with a micropipette to the vial containing the sodium. Hydrazine was observed to react violently upon contact with sodium, indicated by fuming, followed by vigorous bubbling. Once the bubbling subsided, an additional 1.5 mL N₂H₄ was added to the vial. In another two separate vials, the In₂Se₃ and Cu₂S solutions were prepared. 1 mmol of indium selenide (In₂Se₃) was mixed in 4 mL of hydrazine. The initially dark solution gradually turned into a transparent viscous oil-like solution after a few days of continuous stirring. For the Cu₂S precursor, 1 mmol of copper sulfide (Cu₂S) and 2 mmol of sulfur (S) were mixed in 4 mL of hydrazine. An initially blackish-yellow colored solution gradually became a transparent yellow solution after several days of continuous stirring. After both metal chalcogenides had completely dissolved, both mixtures were filtered to remove any insoluble species. Finally, the precursor solution was prepared by mixing the In₂Se₃, Cu₂S, and Na-solutions in various ratios.

In order to observe the effect of grain growth, samples were prepared by first sputtering 1 μm of molybdenum (Mo) on a silicon substrate. Mo was used in order to provide better adhesion as well as to the mimic surface morphology used to fabricate solar cells. The Mo-sputtered substrate was then cleaned with O₂/plasma treatment prior to depositing the CuInSSe layer via drop casting. The cast film was left in a glass petri dish to air dry, followed by annealing in Ar at 500° C. for 10 hours. All experimental procedures described in solution preparation and film deposition were carried out in an inert atmosphere.

A CuInSSe solar cell was fabricated to observe the effect of grain boundary passivation due to sodium. The solar cell was fabricated by first sputtering 30 nm of molybdenum (Mo) on an ITO coated glass substrate. Mo was used in order to provide better adhesion. The Mo-sputtered substrate was then cleaned with O₂/plasma treatment prior to depositing the CuInSSe layer via drop casting. The cast film was placed on a programmable heat plate and annealed at 370° C. for 30 min to convert from precursor to CuInSSe. All experimental procedures described in solution preparation and film deposition were carried out in an inert atmosphere. Afterwards, the buffer layer using CdS was deposited by chemical-bath deposition, and the window layer using intrinsic ZnO and ITO was deposited by sputtering.

Cross-sectional micrographs of the film were characterized using Joel JSM-6700F field emission scanning electron microscope (SEM) with a 10 kV accelerating voltage and a 5 mm working distance.

Results and discussion

### Effect of Grain Growth

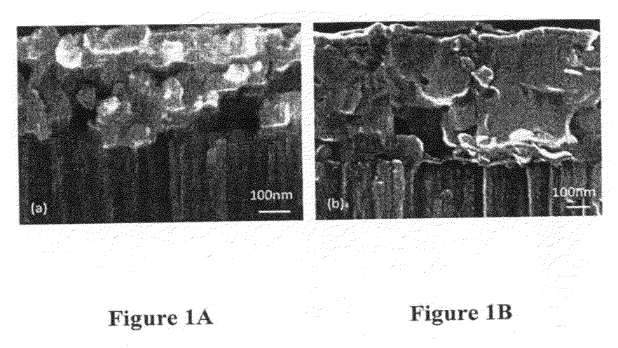

FIG. 1A shows an SEM micrograph, in cross-sectional view, of the pristine CuInSSe sample after annealing. The film appeared grainy with grain size of approximately 100 nm. FIG. 1B shows the CuInSSe film that was deposited with the addition of Na solution during casting. Using the same annealing profile as the pristine CuInSSe sample, the addition of Na showed a significant increase in grain size. The largest grain in Na-incorporated CuInSSe film was as large as the thickness of the film, which is approximately 500 nm. It is very likely that the grain size in FIG. 1B is limited by the film thickness. Thus, larger grain size could be achieved with thicker film.

### Effect of Grain Boundary Passivation

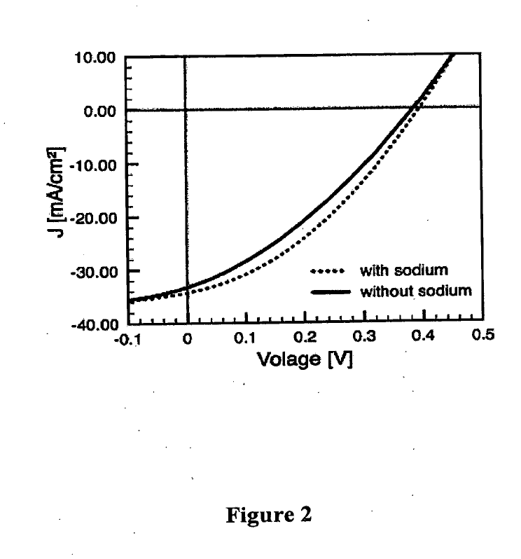

Due to the polycrystalline nature of the CuInSSe material, the grain boundary can be a source of trap sites for the photogenerated carriers, causing them to recombine before being extracted. The presence of sodium in CuInSSe is known to passivate the grain boundary (David Cahen, Adv. Mater. 1998, 10, No. 1, 31-36), decreasing the recombination effect, and allowing more carriers to be extracted. The effect of sodium on the photovoltaic performance of CuInSSe solar cell is shown in FIG. 2. The solar cell device fabricated from sodium-incorporated CISS showed improved efficiency compared to the device without sodium. Based on the photovoltaic parameters (Table 1), the increase in the solar cell efficiency is mainly due to improvements in the fill factor.

TABLE 1
Photovoltaic parameters extracted from the J-V characteristics
of FIG. 2.

| | V_{oc} | J_{sc} | PCE | FF |
|---|---|---|---|---|
| | (V) | (mA/cm²) | (%) | (%) |
| with sodium | 0.39 | 33.27 | 4.20 | 32.67 |
| without sodium | 0.40 | 34.30 | 4.94 | 36.23 |

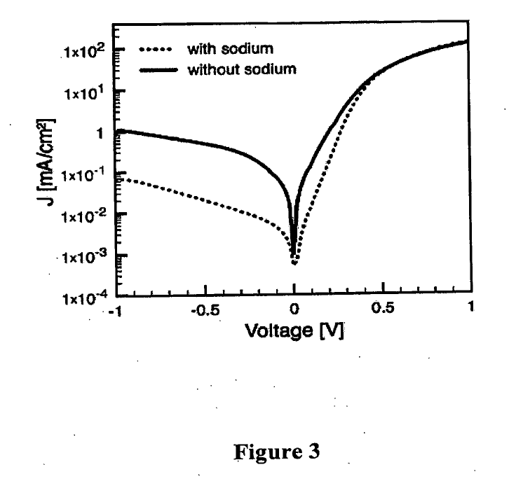

The J-V characteristics under dark (FIG. 3) conditions showed a significant decrease in the leakage current. The saturation current (Iₒ) extracted from dark J-V (Table 2) showed a decrease of greater than one order of magnitude when sodium was incorporated. The decrease in saturation current is a strong indication of decrease in carrier recombination, which explains the reason for the fill factor improvement observed in the solar cell performance.

TABLE 2
Diode parameters extracted from the J-V characteristics of FIG. 3.

| | Rₛ | Rₛₕ | | I₀ |
|---|---|---|---|---|
| | (Ω) | (Ω) | n | (A) |
| with sodium | 62.77 | 1.10 × 10⁶ | 1.53 | 8.07 × 10⁻⁸ |
| without | 46.35 | 3.74 × 10⁴ | 1.90 | 1.49 × 10⁻⁶ |
| sodium | | | | |

Conclusions from the Example

This example demonstrated the effect of sodium in assisting in the grain growth and passivating the grain boundary of semiconducting CuInSSe material. Also, this example demonstrated a simple yet elegant method to incorporate alkali metals into solution-processed crystalline semiconductors. In addition to adding Na solution to a precursor solution as demonstrated here, this method can also be used to increase the size of pre-formed particles while still in a suspension. This method can be particularly advantageous for introducing Na into the CIS layer for the top cell in tandem structure, for example. In addition, this method can offer a wider range of substrates that can be used to fabricated highly efficient CISS solar cells.

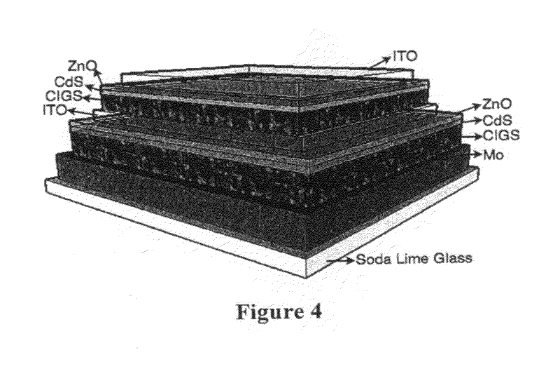

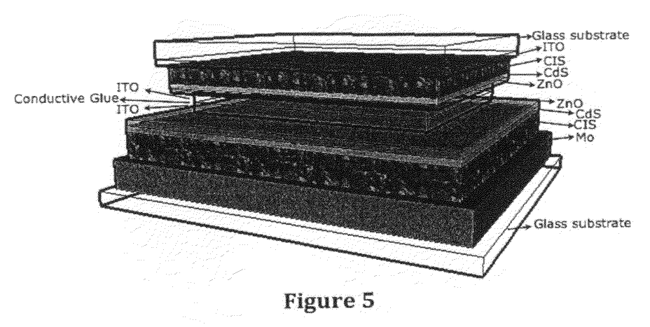

FIGS. 4 and 5 illustrate examples of tandem semiconductor devices that can be produced according to some embodiments of the current invention.

The embodiments illustrated and discussed in this specification are intended only to teach those skilled in the art the best way known to the inventors to make and use the invention. Figures are not drawn to scale. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. A precursor solution for producing a semiconductor, comprising:
at least one of an alkali metal or an alkali metal compound dissolved in a solvent; and
a metal chalcogenide dissolved in said solvent.

2. A precursor solution according to claim 1, wherein said metal chalcogenides comprise at least one of Cu, In, Ga, Zn, Sn, Na, K, Al and P.

3. A precursor solution according to claim 1, wherein said metal chalcogenides comprise at least one of Cu₂Se, Cu₂Te, In₂S₃, In₂Te₃, CdTe, CdSe, CdS, Ga₂S₃, and Ga₂Se₃.

4. A precursor solution according to claim 1, wherein said metal chalcogenides comprise In₂Se₃ and Cu₂S.

5. A precursor solution according to claim 1, wherein said solvent is hydrazine.

6. A precursor solution according to claim 1, wherein said at least one of an alkali metal or alkali metal compound comprises at least one of Li, Na, K, Rb, Cs and Fr.

7. A precursor solution according to claim 1, wherein said at least one of an alkali metal or alkali metal compound comprises an alkali metal salt.

8. A precursor solution according to claim 1, wherein said at least one of an alkali metal or alkali metal compound comprises at least one of a carbonate, hydroxide or chalcogenide derivative alkali metal compound.

9. A precursor solution according to claim 1, wherein said at least one of an alkali metal or alkali metal compound comprises Na.

10. A method of producing a precursor solution for producing a semiconductor, comprising:
preparing a first precursor solution comprising at least one of an alkali metal or an alkali metal compound dissolved in a first solvent;
preparing a second precursor solution comprising a metal chalcogenide dissolved in a second solvent; and
combining said first and second precursor solutions to obtain said precursor solution for producing said semiconductor.

11. A method of producing a precursor solution according to claim 10, further comprising preparing a third precursor solution comprising a second metal chalcogenide dissolved in a third solvent prior to said combining; and combining said third precursor solution with at least one of said first and second precursor solutions prior to said combining or during said combining.

12. A method of producing a precursor solution according to claim 11, wherein said first, second and third solvents are substantially the same solvents.

13. A method of producing a precursor solution according to claim 10, wherein said metal chalcogenides comprise at least one of Cu, In, Ga, Zn, Sn, Na, K, Al and P.

14. A method of producing a precursor solution according to claim 10, wherein said metal chalcogenides comprise at least one of Cu₂Se, Cu₂Te, In₂S₃, In₂Te₃, CdTe, CdSe, CdS, Ga₂S₃, and Ga₂Se₃.

15. A method of producing a precursor solution according to claim 10, wherein said metal chalcogenides comprise In₂Se₃ and Cu₂S.

16. A method of producing a precursor solution according to claim 12, wherein said solvent is hydrazine.

17. A method of producing a precursor solution according to claim 10, wherein said at least one of an alkali metal or alkali metal compound comprises at least one of Li, Na, K, Rb, Cs and Fr.

18. A method of producing a precursor solution according to claim 10, wherein said at least one of an alkali metal or alkali metal compound comprises an alkali metal salt.

19. A method of producing a precursor solution according to claim 10, wherein said at least one of an alkali metal or alkali metal compound comprises at least one of a carbonate, hydroxide or chalcogenide derivative alkali metal compound.

20. A method of producing a precursor solution according to claim 10, wherein said at least one of an alkali metal or alkali metal compound comprises Na.

21. A method of producing a semiconductor device, comprising:
providing a precursor solution for producing a semiconductor layer on a substructure; and
forming a layer of said precursor solution on said substructure,
wherein said precursor solution comprises at least one of an alkali metal or an alkali metal compound dissolved in a solvent, and a metal chalcogenide dissolved in said solvent.

22. A method of producing a semiconductor device according to claim 21, further comprising bringing said substructure substantially to a predetermined temperature such that volatile components of said layer of said precursor solution at least one of evaporate or migrate from said layer as said layer of precursor solution becomes said semiconductor layer.

23. A method of producing a semiconductor device according to claim 21, further comprising additional processing subsequent to said forming said layer of said precursor solution on said substructure.

24. A method of producing a semiconductor device according to claim 21, wherein said substructure is a complex substructure comprising a plurality of layers of materials.

25. A method of producing a semiconductor device according to claim 21, wherein said complex substructure includes at least one semiconductor sub-device such said producing a semiconductor device produces a tandem semiconductor device that has at least two tandem semiconductor sub-devices.

26. A method of producing a semiconductor device according to claim 21, wherein said metal chalcogenides comprise at least one of Cu, In, Ga, Zn, Sn, Na, K, Al and P.

27. A method of producing a semiconductor device according to claim 21, wherein said metal chalcogenides comprise at least one of Cu₂Se, Cu₂Te, In₂S₃, In₂Te₃, CdTe, CdSe, CdS, Ga₂S₃, and Ga₂Se₃.

28. A method of producing a semiconductor device according to claim 21, wherein said metal chalcogenides comprise In₂Se₃ and Cu₂S.

29. A method of producing a semiconductor device according to claim 21, wherein said solvent is hydrazine.

30. A method of producing a semiconductor device according to claim 21, wherein said at least one of an alkali metal or alkali metal compound comprises at least one of Li, Na, K, Rb, Cs and Fr.

31. A method of producing a semiconductor device according to claim 21, wherein said at least one of an alkali metal or alkali metal compound comprises an alkali metal salt.

32. A method of producing a semiconductor device according to claim 21, wherein said at least one of an alkali metal or alkali metal compound comprises at least one of a carbonate, hydroxide or chalcogenide derivative alkali metal compound.

33. A method of producing a semiconductor device according to claim 21, wherein said at least one of an alkali metal or alkali metal compound comprises Na.

34. A semiconductor device produced according to claim 21.
